(19) United States
(12) Patent Application Publication
(10) Pub. No.: US 2025/0306468 A1
(43) Pub. Date: Oct. 2, 2025

(54) MULTIPATTERNING WITH CROSSLINKABLE OVERCOAT

(71) Applicant: Tokyo Electron Limited, Tokyo (JP)

(72) Inventors: Michael Murphy, Niskayuna, NY (US); Jodi Grzeskowiak, Schenectady, NY (US); David Conklin, Saratoga Springs, NY (US)

(21) Appl. No.: 18/617,380

(22) Filed: Mar. 26, 2024

(51) Int. Cl. G03F 7/20; G03F 7/16; G03F 7/32; G03F 7/42; H01L 21/02; H01L 21/027; H01L 21/033

(52) U.S. Cl. CPC G03F 7/2043; G03F 7/168; G03F 7/2004; G03F 7/32; G03F 7/422; H01L 21/02348; H01L 21/0274; H01L 21/0337

(57) ABSTRACT

An example method of processing a substrate includes patterning a photoresist deposited over the substrate to form a plurality of mandrels, and spin coating an overcoat material over the plurality of mandrels. The method includes exposing the substrate to an ultraviolet (UV) irradiation to generate acid in the plurality of mandrels; diffusing the acid into a portion of the overcoat material. The diffused acid induces a crosslinking reaction in the portion to form a crosslinked portion of the overcoat material. The method includes performing a developing process using a developing solution to remove the plurality of mandrels and the overcoat material except the crosslinked portion of the overcoat material.

### TECHNICAL FIELD

The present invention relates generally to methods of processing a substrate, and, in particular embodiments, to multipatterning with crosslinkable overcoat.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

Photolithography is a common patterning method in semiconductor fabrication. A photolithography process may start by exposing a coating of photoresist comprising a radiation-sensitive material to a pattern of actinic radiation to define a relief pattern. For example, in the case of positive photoresist, irradiated portions of the photoresist may be dissolved and removed by a developing step using a developing solvent, forming the relief pattern of the photoresist. The relief pattern then may be transferred to a target layer below the photoresist or an underlying hard mask layer formed over the target layer. Innovations on photolithographic techniques may be needed to satisfy the cost and quality requirements for patterning at nanoscale features.

### SUMMARY

In accordance with an embodiment, a method of processing a substrate includes patterning a photoresist deposited over the substrate to form a plurality of mandrels; spin coating an overcoat material over the plurality of mandrels; exposing the substrate to an ultraviolet (UV) irradiation to generate acid in the plurality of mandrels; diffusing the acid into a portion of the overcoat material. The diffused acid may induce a crosslinking reaction in the portion to form a crosslinked portion of the overcoat material. The method includes performing a developing process using a developing solution to remove the plurality of mandrels and the overcoat material except the crosslinked portion of the overcoat material.

In accordance with an embodiment, a method of processing a substrate includes patterning a photoresist deposited over the substrate to form a plurality of mandrels, and spin coating an overcoat material over the plurality of mandrels. The method includes inducing a crosslinking reaction in the overcoat material; exposing the substrate to an ultraviolet (UV) irradiation to generate acid in the plurality of mandrels; diffusing the acid into a portion of the crosslinked overcoat material, the diffused acid inducing a de-crosslinking reaction in the portion. The method includes performing a developing process using a developing solution to selectively remove the de-crosslinked portion of the overcoat material.

In accordance with an embodiment, a method of double patterning includes forming a first relief pattern including a mandrel over a substrate, and spin coating an overcoat material over the mandrel, the overcoat material including a crosslinker. The method includes exposing the substrate to an ultraviolet (UV) irradiation to generate acid in the mandrel; diffusing the acid into portions of the overcoat material. The diffused acid may induce a crosslinking or de-crosslinking reaction in the portions. The method includes performing a development process to form a second relief pattern defined by the portions, a pitch size of the second relief pattern is less than that of the first relief pattern.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1G illustrate cross sectional views of an example substrate at different stages of a method of spacer multiple patterning using a crosslinkable overcoat in accordance with various embodiments, wherein FIG. 1A illustrates an incoming substrate comprising photoresist mandrels, FIG. 1B illustrates the substrate after depositing the crosslinkable overcoat, FIG. 1C illustrates the substrate after an etch back to remove an overburden, FIG. 1D illustrates the substrate after an exposure to an actinic radiation, FIG. 1E illustrates the substrate after acid diffusion into the crosslinkable overcoat, FIG. 1F illustrates the substrate after a development step, and FIG. 1G illustrates the substrate after a pattern transfer;

FIGS. 2A-2B illustrates two example process flows for spacer patterning in accordance with certain embodiments, wherein FIG. 2A illustrates a deposition-first process, and wherein FIG. 2B illustrates an exposure-first process;

FIGS. 3A-3G illustrate cross sectional views of another example substrate at different stages of a method of antispacer multiple patterning using a reversible overcoat in accordance with alternate embodiments, wherein FIG. 3A illustrates an incoming substrate comprising photoresist mandrels, FIG. 3B illustrates the substrate after depositing the reversible overcoat, FIG. 3C illustrates the substrate after overcoat crosslinking, FIG. 3D illustrates the substrate after an exposure to an actinic radiation, FIG. 3E illustrates the substrate after acid diffusion into the crosslinked overcoat, FIG. 3F illustrates the substrate after a development step, and FIG. 3G illustrates the substrate after a pattern transfer;

FIGS. 4A-4B illustrates two example process flows for antispacer patterning in accordance with certain embodiments, wherein FIG. 4A illustrates a deposition-first process, and wherein FIG. 4B illustrates an exposure-first process; and

FIG. 5A-5C illustrate process flow charts of methods of multipatterning in accordance with various embodiments, wherein FIG. 5A illustrates one embodiment of spacer patterning, FIG. 5B illustrates another embodiment of antispacer patterning, and FIG. 5C illustrates yet another embodiment for spacer or antispacer patterning.

### DETAILED DESCRIPTION OF ILLUSTRATIVE EMBODIMENTS

This application relates to methods of processing a substrate, and, in particular embodiments, to the process of multipatterning that uses chemically amplified photoresists (CAR) and a crosslinkable overcoat. Various embodiments use acid diffusion from photoresist mandrel into the overcoat for spacer or antispacer patterning to improve lithographic techniques. Generally, lithography tools are a prime example of technological innovation to meet next generation semiconductor requirements such as the shift from 193 immersion to extreme ultraviolet (EUV) to high NA EUV. However, high cost and process limitations are gating factors for many companies to utilize the most advanced processes. Thus, alternative patterning schemes such as self-aligned double patterning (SADP), self-aligned block (SAB), self-aligned litho etch litho etch (SALELE) and other schemes have found prevalent use within the market. Even these established alternate schemes requires numerous inorganic film depositions and etch transfers, are complex and costly.

Various embodiments of the methods in this disclosure enable multipatterning sub-resolution features through only spin-on materials, thereby advantageously removing the need for slow inorganic depositions and numerous hardmask transfers. Design of the overcoat composition can allow for the formation of either lines (via spacer patterning) or trenches (via antispacer patterning), which may have a pitch size below the optical resolution of the photolithographic technique applied to form the photoresist mandrel. In various embodiments, spacers or antispacers may be formed by acid-catalyzed reaction in the overcoat, where the acid required for the reaction may be generated in and diffused from the photoresist mandrel. The critical dimensions (CD) of the spacers or antispacers may be defined by acid diffusion distance. The overcoat may comprise a crosslinker, in certain embodiments, with reversibility (switchable crosslinking mechanism). In spacer patterning applications, the acid diffused into a portion of the overcoat can induce a crosslinking reaction and define the spacers. In antispacer patterning application, the overcoat may be cured and crosslinked first, and the acid diffused can induce a de-crosslinking reaction in a portion of the crosslinked overcoat, defining antispacers. The methods of multipatterning in this disclosure can thus enable sub-lithographic patterning without the use of advanced exposure systems nor the deposition of gas phase inorganic films to act as spacers. The use of crosslinking mechanism at the pattern interface but not within the photoresist mandrel allows for finer CD and line edge roughness (LER) control without alteration to the photoresist formulation.

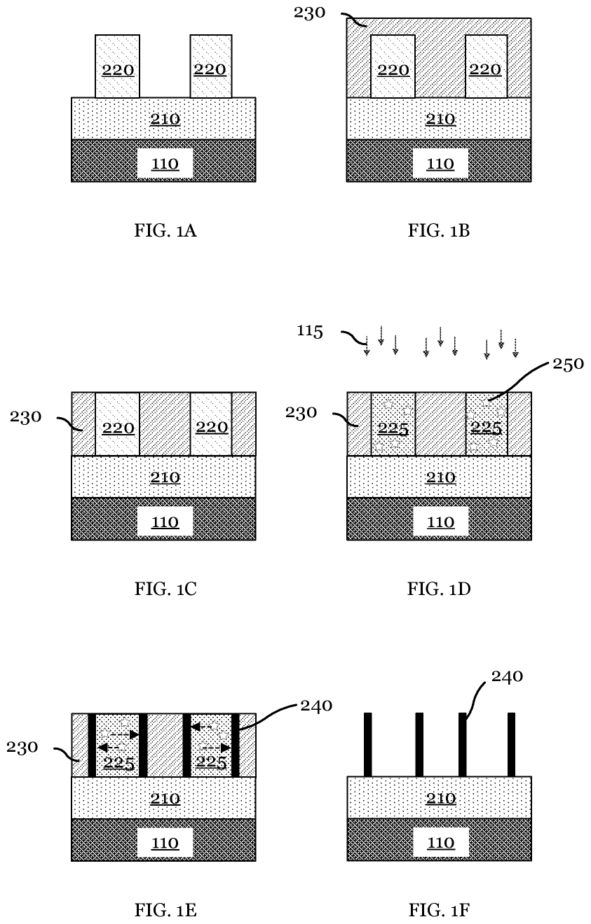

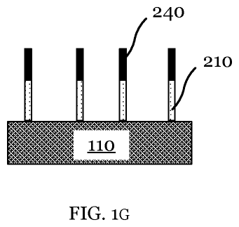

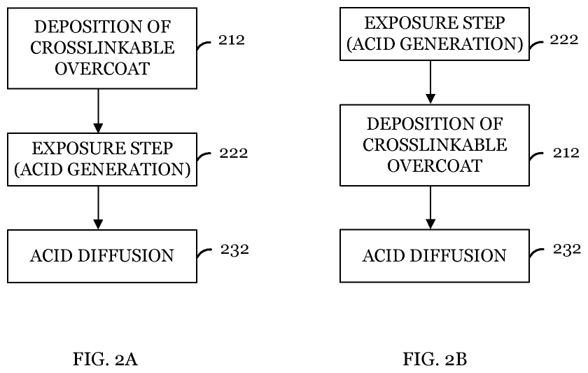

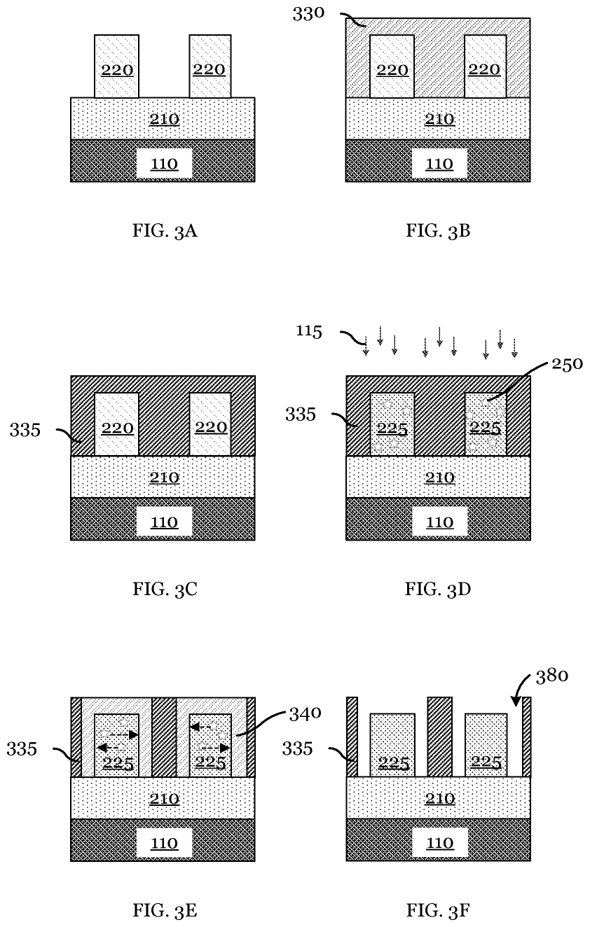

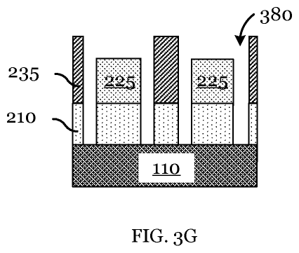

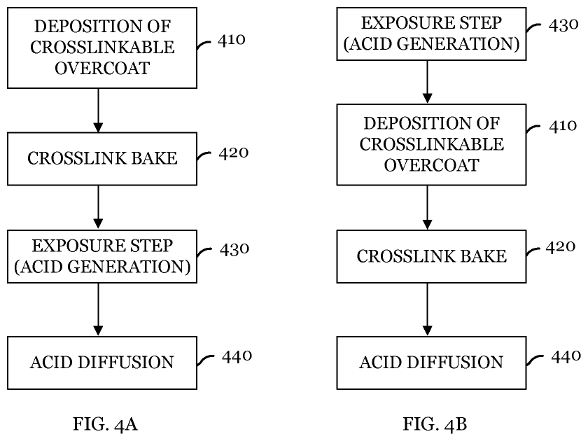

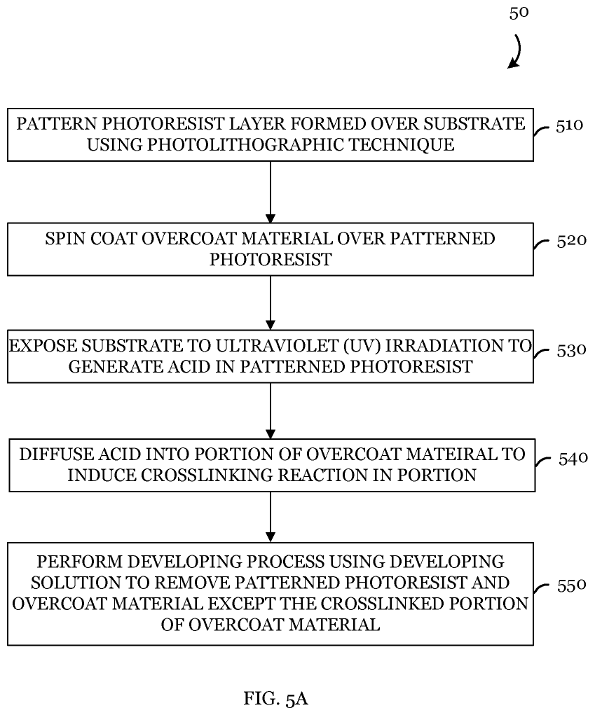

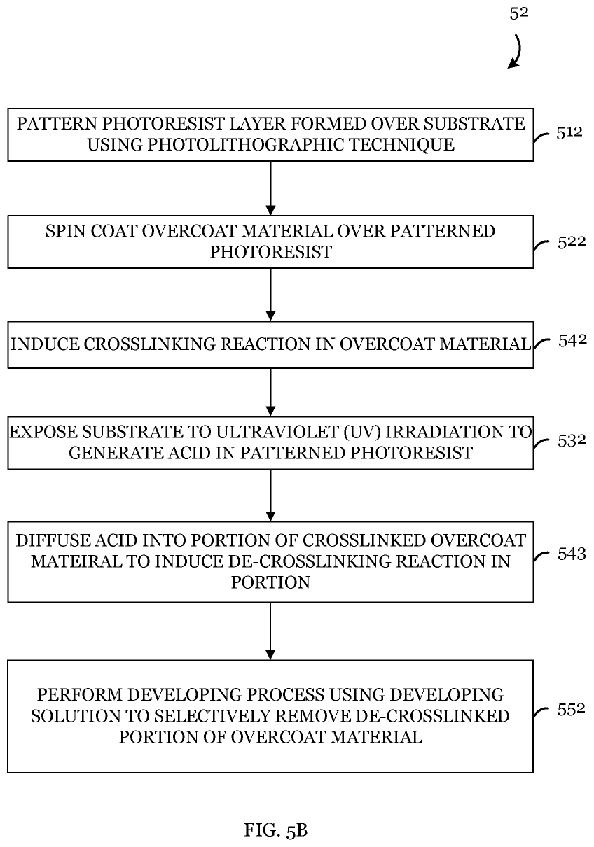

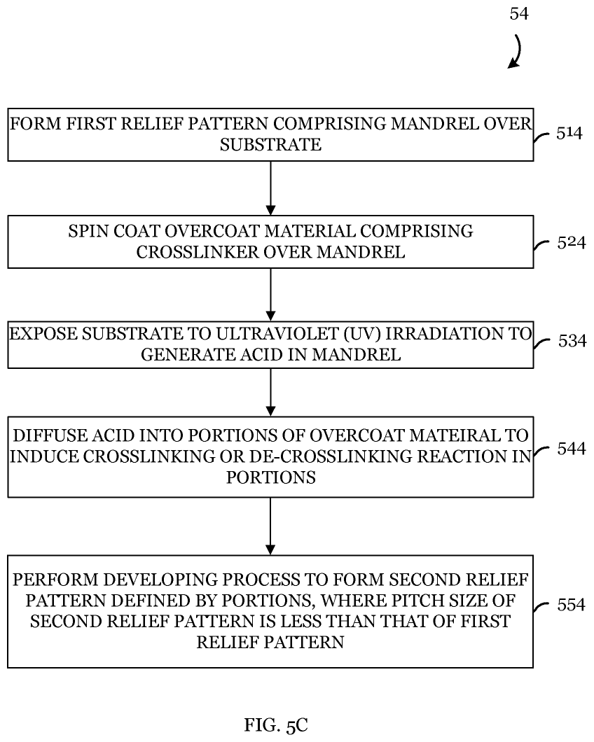

In the following, a process of multipatterning with crosslinkable overcoat to form sub-resolution features is described. A spacer patterning method is described first referring to FIGS. 1A-1G and 2A-2B, and an antispacer patterning method is then described referring to FIGS. 3A-3G and 4A-4B. Several embodiment process flows of multipatterning are described referring to FIGS. 5A-5C. All Figures in the disclosure, including the aspect ratios of features, are not to scale and for illustration purposes only.

In this disclosure, sacrificial structures adjacent to the photoresist mandrel used to form trenches or any recesses are referred to as “antispacers.” Overcoat materials comprising a crosslinker is generally referred to as crosslinkable overcoat (FIGS. 1A-1G), and also reversible overcoat when the material has the ability of crosslinking and de-crosslinking (FIGS. 3A-3G). Further, any list that presents possible compositions, conditions, or process variations includes any reasonable combination thereof, and thus the term “or” used in the list does not indicate any exclusive selection of a particular composition, condition, or process variation.

FIGS. 1A-1G illustrate cross sectional views of an example substrate at different stages of a method of spacer multiple patterning using a crosslinkable overcoat in accordance with various embodiments.

FIG. 1A illustrates a cross sectional view of an incoming substrate 110 comprising photoresist mandrels 220.

The substrate 110 may be a part of, or include, a semiconductor device, and may have undergone a number of steps of processing following, for example, a conventional process. The substrate 110 accordingly may comprise layers of semiconductors useful in various microelectronics. For example, the semiconductor structure may comprise the substrate 110 in which various device regions are formed.

In one or more embodiments, the substrate 110 may be a silicon wafer, or a silicon-on-insulator (SOI) wafer. In certain embodiments, the substrate 110 may comprise a silicon germanium wafer, silicon carbide wafer, gallium arsenide wafer, gallium nitride wafer and other compound semiconductors. In other embodiments, the substrate 110 comprises heterogeneous layers such as silicon germanium on silicon, gallium nitride on silicon, silicon carbon on silicon, as well layers of silicon on a silicon or SOI substrate. In various embodiments, the substrate 110 is patterned or embedded in other components of the semiconductor device.

The semiconductor structure may have undergone a number of steps of processing following, for example, a conventional process. For example, the semiconductor structure may comprise a substrate 110 in which various device regions are formed. At this stage, the substrate 110 may include isolation regions such as shallow trench isolation (STI) regions as well as other regions formed therein.

In FIG. 1A, the substrate 110 may comprise an intermediate layer 210 formed over the substrate 110. The intermediate layer 210 may be a target for pattern transfer in subsequent processing after the antispacer patterning. In various embodiments, the intermediate layer 210 may comprise silicon, silicon oxynitride, organic material, non-organic material, or amorphous carbon. In certain embodiments, the intermediate layer 210 may also be selected to have anti-reflective properties such as by using a silicon bottom anti-reflective coating (Si-BARC). In one or more embodiments, the intermediate layer 210 may be a mask layer comprising a hard mask. The hard mask may comprise silicon nitride, silicon dioxide (SiO₂), or titanium nitride. Further, the intermediate layer 210 may be a stacked hard mask comprising, for example, two or more layers using two different materials. A first layer of the hard mask may comprise a metal-based layer such as titanium nitride, titanium, tantalum nitride, tantalum, tungsten based compounds, ruthenium based compounds, or aluminum based compounds, and a second layer of the hard mask may comprise a dielectric layer such as silicon dioxide, silicon nitride, silicon oxynitride, silicon carbide, amorphous silicon, or polycrystalline silicon. The intermediate layer 210 may be deposited using deposition techniques such as vapor deposition including chemical vapor deposition (CVD), physical vapor deposition (PVD), and atomic layer deposition (ALD), as well as other plasma processes such as plasma enhanced CVD (PECVD), sputtering, and other processes.

Still referring to FIG. 1A, photoresist mandrels 220 may be formed over the intermediate layer 210. The photoresist mandrels 220 may be a patterned photoresist, which may be formed by conventional methods. In certain embodiments, a layer of a photoresist may be deposited over the intermediate layer 210, e.g., using a coating process or a spin-on process. In various embodiments, the photoresist may comprise a light sensitive organic material, and may be applied from a solution by, for example, a conventional spin coating technique. In some embodiments, the photoresist may comprise a positive tone resist or alternatively a negative tone resist. For example, a standard TMAH type development would remove a negative tone resist mandrel when forming the antispacer. However, the use of an organic solvent such as 4-methyl-2-pentanol or n-butyl acetate may remove the de-crosslinked overcoat selective to the photoresist mandrel thereby forming antispacer trenches from a negative tone mandrel. The use of an negative tone resist process within the antispacer flow may use a reaction scheme in which crosslinking and decrosslinking occur simultaneously. The acid diffusing out of the photoresist mandrel during a bake post overcoat deposition will either cause alternative reactions to occur which will not inhibit solubility or cause decrosslinking base on the reaction and diffusion kinetics. The points in which the acid does not diffuse within the overcoat volume would become crosslinked and insoluble. In various embodiments, the photoresist may comprise a solubility-changing agent necessary for the initial patterning of forming the mandrel. The solubility-changing agent may comprise a photo-acid generator (PAG). As further described below referring to FIG. 1D, the PAG in the photoresist mandrel 220 may be used to generate acid necessary to induce crosslinking or de-crosslinking for spacer or antispacer formation. In one or more embodiments, the photoresist may further comprise an acid amplifier (AA).

In various embodiments, a conventional photolithographic process (e.g., soft bake, actinic radiation exposure, post-exposure bake, and development) may be used to pattern the photoresist. The exposure step may be performed using a photolithographic technique such as dry lithography (e.g., using 193 dry lithography), immersion lithography (e.g., using 193 nanometer immersion lithography), i-line lithography (e.g., using 365 nanometer wavelength UV radiation for exposure), H-line lithography (e.g., using 405 nanometer wavelength UV radiation for exposure), extreme UV (EUV) lithography, deep UV (DUV) lithography, or any suitable photolithography technology. Additionally, the photolithography technology may be mask-based (e.g., projection lithography), maskless (e.g., e-beam lithography), or another suitable type of lithography. In one or more embodiments, deep ultraviolet (DUV) and/or immersion lithography may be used. As described below in various embodiments, antispacer patterning enables forming features having a pitch size below the optical resolution of the photolithographic technique used to form the photoresist mandrels 220. In one embodiment, a post-exposure bake may be performed by thermally treating the substrate 110, for example, at 60-140° C. The developing step may be performed by a conventional developing method. In various embodiments, the developing solution may comprise a metal iron free (MIF) developer, for example, an aqueous solution of tetramethylammonium hydroxide (TMAH). In other embodiments, the developing solution may comprise a metal ion containing developer, for example, an aqueous solution of sodium hydroxide (NaOH) or potassium hydroxide (KOH). As a result, a pattern of the photoresist (e.g., lines in FIG. 1B) is formed over the intermediate layer 210 as the photoresist mandrels 220.

The photoresist mandrels 220 may have any suitable thickness, which also may be referred to as height. In certain embodiments, the photoresist mandrels 220 have a thickness of 5 nm to 5 μm, for example 50 nm to 200 nm. Further, the critical dimension (CD) of the photoresist mandrel 220 may be any size enabled by the photolithographic technique applied. In one embodiment, the CD may be 200 nm or less. The photoresist mandrels 220 define the first relief pattern where antispacers may be formed for double patterning. Various embodiments of the methods reduce the CD of the first relief pattern through antispacer patterning, and forms smaller features, for example, with a CD less than 100 nm, e.g., in the range of 10-40 nm.

FIG. 1B illustrates a cross sectional view of the substrate 110 after depositing a crosslinkable overcoat 230.

In FIG. 1B, the crosslinkable overcoat 230 is deposited as an overcoat material over the substrate 110, covering the photoresist mandrel 220. In various embodiments, the crosslinkable overcoat 230 may be deposited using a coating process or a spin-on process. Any reasonable solvent system that is immiscible with the photoresist material used for the photoresist mandrel 220 may be used for depositing the crosslinkable overcoat 230. In FIG. 1B, the crosslinkable overcoat 230 covers the top surface of the photoresist mandrel 220 in addition to their sidewalls. In another embodiment, a portion of the top surface of the photoresist mandrel 220 may be left uncovered by the crosslinkable overcoat 230. In various embodiments, the crosslinkable overcoat 230 may comprise a crosslinker that undergoes crosslinking in the presence of acid, and have a different composition from the photoresist mandrel 220. Although the crosslinkable overcoat 230 is illustrated as a single uniform layer in FIG. 1B, in other embodiments, more than one material layer or composition may be used for the crosslinkable overcoat 230.

In certain embodiments, an overcoat bake treatment may be performed after depositing the crosslinkable overcoat 230 and prior to a subsequent exposure step (e.g., FIG. 1D). In one embodiment, the overcoat bake may be performed by thermally treating the substrate 110, for example, at 80-160° C.

FIG. 1C illustrates a cross sectional view of the substrate 110 after an etch back to remove an overburden.

In certain embodiments, an etch back may be performed to remove any overburden of the crosslinkable overcoat 230 to expose the top surface of the photoresist mandrels 220 prior to subsequent process steps (e.g., acid diffusion for crosslinking). In one embodiment, the etch back may be performed by a controllable solvent recess based on a low innate dissolution rate in a selective solvent.

FIG. 1D illustrates a cross sectional view of the substrate 110 after an exposure to an actinic radiation.

In FIG. 1D, the exposure step may be performed by exposing the substrate to an actinic radiation 115 with a photomask or maskless. FIG. 1D illustrates an embodiment with a maskless exposure. In embodiments with the photomask, the photomask may have holes or square openings to define the area of spacers.

In various embodiments, the exposure step may be performed using a photolithographic technique such as dry lithography (e.g., using 193 dry lithography), immersion lithography (e.g., using 193 nanometer immersion lithography), i-line lithography (e.g., using 365 nanometer wavelength UV radiation for exposure), H-line lithography (e.g., using 405 nanometer wavelength UV radiation for exposure), EUV lithography, DUV lithography, or any suitable photolithography technology.

Upon the exposure to the actinic radiation 115, the photoresist material forming the photoresist mandrel 220 (FIGS. 1A-1C) may react to form a photo-reacted mandrel 225, which may become soluble in a developing solution. The exposure also generates acid 250 within the photo-reacted mandrel 225 via, for example, the decomposition of the photo-acid generator (PAG) contained in the photoresist material. In various embodiments, process conditions for the exposure step may be selected to generate the acid 250 at a level beyond the threshold necessary for acid diffusion across the interface between the photo-reacted mandrel 225 and the crosslinkable overcoat 230.

FIG. 1E illustrates a cross sectional view of the substrate 110 after acid diffusion into the crosslinkable overcoat.

In various embodiments, after the acid generation by the exposure step, a subsequent process step such as thermal treatment (thermal cure) may be performed to initiate or accelerate the lateral diffusion of the acid 250 from the bulk of the photoresist mandrel 220 into a portion of the crosslinkable overcoat 230. In one embodiment, the diffusion step may be a bake comprising thermally treating the substrate 110, for example, at 80-140° C., 60-100° C. in one embodiment.

The acid 250 diffused can then induce a crosslinking reaction to form crosslinked layers 240 within the overcoat material near its sidewalls. In various embodiments, the crosslinked layers 240 have a solubility different from the unreacted portion of the overcoat material, and therefore may be used to form sidewall spacers by a developing step (e.g., FIG. 1F) using a developing solution that selectively dissolves the unreacted overcoat and the photo-reacted mandrel 225.

The thickness of the crosslinked layers 240 may depend on the diffusivity of the acid 250. Accordingly, the bake temperature and duration, as well as the concentration and composition of the acid in the photoresist and overcoat material, may be selected to control the thickness of the crosslinked layers 240 and consequently the CD of the spacers.

In one or more embodiments, the acid diffusion may immediately occur in response to the exposure step. In one or more embodiments, a bake treatment may be integrated as a part of the exposure step. Although some embodiments, may use acid diffusion without bake, for diffusion lengths of interest this can be poorly controlled and take prolonged amounts of time. Accordingly, generally in or more embodiments, use a bake treatment.

FIG. 1F illustrates a cross sectional view of the substrate 110 after a development step.

In FIG. 1F, the substrate 110 may be treated by a developing solvent by a conventional developing method. In certain embodiments, the developing solvent may comprise an aqueous solution of tetramethylammonium hydroxide (TMAH), but other solvents may be used in other embodiments. After developing, the unreacted portion of the crosslinkable overcoat 230 as well as the photo-reacted mandrel 225 are selectively removed, leaving the crosslinked layers 240 as self-standing spacers.

FIG. 1G illustrates a cross sectional view of the substrate 110 after a pattern transfer.

In FIG. 1G, the intermediate layer 210 may be etched by an anisotropic etching process, such as reactive ion etch (RIE). The anisotropic etching process transfers the spacer pattern defined by the crosslinked layers 240 to the intermediate layer 210.

FIGS. 2A-2B illustrates two example process flows for spacer patterning in accordance with certain embodiments, wherein FIG. 2A illustrates a deposition-first process, and wherein FIG. 2B illustrates an exposure-first process.

The order of overcoat deposition and actinic radiation exposure can be manipulated for throughput and process window control by altering the absorptivity and composition of the overcoat film. For example, in the position-first process, as described above referring to FIGS. 1A-1G, the overcoat deposition (block 212) is performed prior to the exposure step (block 222) for acid generation, which is then followed by the acid diffusion (block 232) as illustrated in FIG. 2A. In other embodiments, the exposure step (block 222) may precede the overcoat deposition (block 212), which is followed by the acid diffusion (block 232) as illustrated in FIG. 2B.

In addition to spacer patterning, the methods of this disclosure may also be applied in antispacer patterning.

FIGS. 3A-3G illustrate cross sectional views of another example substrate at different stages of a method of antispacer multiple patterning using a reversible overcoat in accordance with alternate embodiments.

FIG. 3A illustrates a cross sectional view of an incoming substrate 110 comprising photoresist mandrels 220. The details of the materials and structures of the substrate 110 may be identical or similar to those in FIG. 1A, and will not be repeated.

FIG. 3B illustrates a cross sectional view of the substrate 110 after depositing a reversible overcoat 330.

In FIG. 1B, the reversible overcoat 330 is deposited as an overcoat material over the substrate 110, covering the photoresist mandrel 220. In various embodiments, the reversible overcoat 330 may be deposited using a coating process or a spin-on process. Any reasonable solvent system that is immiscible with the photoresist material used for the photoresist mandrel 220 may be used. In FIG. 1B, the reversible overcoat 330 covers the top surface of the photoresist mandrel 220 in addition to their sidewalls. In another embodiment, a portion of the top surface of the photoresist mandrel 220 may be left uncovered.

In various embodiments, the reversible overcoat 330 may comprise a crosslinker that undergoes crosslinking by heat and de-crosslinking in the presence of acid, and have a different composition from the photoresist mandrel 220. An example of the reversible mechanism is the use of multifunctional vinyl ether crosslinkers reacting with hydroxyl groups to form acetal linkages. These acetal bonds are highly reactive to acid, and will break in the presence of acid. This reaction reduces the connectivity and molecular weight, thereby increasing solubility of the overcoat. In contrast to prior embodiments of spacer patterning, where the acid diffusion is used to induce crosslinking, antispacer patterning with the reversible mechanism comprise thermal crosslinking without acid and subsequent de-crosslinking by acid diffusion.

FIG. 3C illustrates a cross sectional view of the substrate 110 after overcoat crosslinking.

In FIG. 3C, the overcoat crosslinking may comprise a bake treatment (crosslink bake) to thermally treating the substrate 110. In one embodiment, the crosslink bake may be performed at 80-160° C. After the crosslink bake, the reversible overcoat 330 may be converted into a crosslinked overcoat 335. In various embodiments, as illustrated in FIG. 3C, the entirety of the overcoat material may be crosslinked at this stage.

FIG. 3D illustrates a cross sectional view of the substrate 110 after an exposure to an actinic radiation 115.

In FIG. 3D, the exposure step may be performed by exposing the substrate to an actinic radiation 115 with a photomask or maskless. FIG. 3D illustrates an embodiment with a maskless exposure. The details of the exposure step may be identical or similar to those described referring to FIG. 1D, and will not be repeated. Similar to prior embodiments, in response to the exposure, acid 250 may be generated in photo-reacted mandrel 225. In various embodiments, process conditions for the exposure step may be selected to generate the acid 250 at a level beyond the threshold necessary for acid diffusion across the interface between the photo-reacted mandrel 225 and the crosslinked overcoat 335.

FIG. 3E illustrates a cross sectional view of the substrate 110 after acid diffusion into the crosslinked overcoat.

In various embodiments, after the acid generation by the exposure step, a subsequent process step such as thermal treatment may be performed to initiate or accelerate the lateral diffusion of the acid 250 from the bulk of the photoresist mandrel 220 into a portion of the crosslinkable overcoat 230. In one embodiment, the diffusion step may be a bake comprising thermally treating the substrate 110, for example, at 60-140° C., and 60-100° C. in one or more embodiments.

The acid 250 diffused can then induce a de-crosslinking reaction in a portion crosslinked overcoat 235 to form de-crosslinked layers 340 within the overcoat material near its sidewalls. As illustrated in FIG. 3E, the de-crosslinked layers 230 may also have a lateral portion covering the top surface of the photo-reacted mandrel 225 as a result of vertical acid diffusion. In various embodiments, the de-crosslinked layers 340 have a solubility different from the bulk of the crosslinked overcoat 335, and therefore may be used to form sidewall antispacers by a developing step (e.g., FIG. 3F) using a developing solution that selectively dissolves the de-crosslinked layers 340.

Similar to prior embodiments, the thickness of the de-crosslinked layers 340 may depend on the diffusivity of the acid 250. Accordingly, the bake temperature and duration, as well as the concentration and composition of the acid in the photoresist and overcoat material, may be selected to control the thickness of the de-crosslinked layers 340 and consequently the CD of the antispacers.

In one or more embodiments, the acid diffusion may immediately occur in response to the exposure step. In one or more embodiments, a bake treatment may be integrated as a part of the exposure step.

FIG. 3F illustrates a cross sectional view of the substrate 110 after a development step.

In FIG. 3F, the substrate 110 may be treated by a developing solvent that selectively dissolves the de-crosslinked layers 340. Among chemically amplified photoresist (CAR) technology, a resist film which has undergone reaction with acid is generally insoluble in n-butyl acetate (NBA) allowing for patterning inverse that of standard TMAH development. The inventors of this application identified that the crosslinked overcoat material initially insoluble in NBA becomes soluble upon de-crosslinking. Accordingly, in various embodiments, NBA may be used for the developing solvent for these embodiments.

After developing, the de-crosslinked layers 340 are selectively removed, forming trenches 380 as an antispacer pattern between the sidewalls of the photo-reacted mandrels 225 and the crosslinked overcoat 335.

FIG. 3G illustrates a cross sectional view of the substrate 110 after a pattern transfer.

In FIG. 3G, the intermediate layer 210 may be etched by an anisotropic etching process, such as reactive ion etch (RIE). The anisotropic etching process transfers the spacer pattern defined by the trenches 380 to the intermediate layer 210.

Both in spacer patterning (FIGS. 1A-1G) and antispacer patterning (FIGS. 3A-3G), the transferred pattern in the intermediate layer 210 (FIGS. 1G and 3G) may be formed as part of a multiple patterning process such as self-aligned double patterning (SADP), self-aligned quadruple patterning (SAQP), or any other multiple patterning techniques known within the state of the art. In various embodiments, the transferred pattern may be used to form a contact hole, metal line, gate line, isolation region, and other features useful in semiconductor fabrication.

As described above, the feature pitch defined by the spacers or antispacers is smaller than the initial pitch defined by the mandrel pattern, thereby increasing the feature density. In certain embodiments, critical dimensions (CD) of the photoresist mandrel and spacers or antispacers (defined by the acid diffusion length) may be selected such that a resulting feature pitch for a line-space-line-space pattern is 1:1:1:1; however, this disclosure contemplates other feature pitches.

FIGS. 4A-4B illustrates two example process flows for antispacer patterning in accordance with certain embodiments, wherein FIG. 4A illustrates a deposition-first process, and wherein FIG. 4B illustrates an exposure-first process.

The order of overcoat deposition, crosslink bake, actinic radiation exposure, and acid diffusion for de-crosslinking can be manipulated for throughput and process window control by altering the absorptivity and reaction kinetics of the overcoat film. For example, in the position-first process, as described above referring to FIGS. 2A-2G, the overcoat deposition (block 410) is followed by the crosslink bake (block 420). After the crosslink bake, the exposure step for acid generation (block 430) and the acid diffusion (block 440) are performed as illustrated in FIG. 4A. In other embodiments, the exposure step (block 430) may be performed first, followed by the overcoat deposition (block 410), the crosslink bake (block 420), and the acid diffusion (block 440) in this order as illustrated in FIG. 3B. In the exposure-first process (e.g., FIG. 4B), in certain embodiments, the steps of crosslink bake and acid diffusion may be combined to a single thermal treatment.

The inventors of this application have experimentally have proven the applicability of switchable crosslinking mechanism in controlled solubility shift in the overcoat material. De-crosslinking induced by acid diffusion from a photoresist has been studied with a bilayer test substrate. In these experiments, a spin-on film (e.g., ˜80 nm in thickness) comprising a crosslinker was applied to a test wafer and thermally crosslinked. Subsequently, a photoresist film comprising a carrier polymer and photo-acid generator (PAG) was deposited over the crosslinked film, and the test wafer was exposed to an UV radiation with a varying exposure dose across the test wafer. The UV exposure generates acid in the photoresist film with an acid content gradient corresponding to the varying exposure dose. A post-exposure bake was performed to diffuse the acid generated by the UV exposure across the interface into the crosslinked film and caused decrosslinking. Finally, the test wafer was treated for developing in 0.26 N TMAH aqueous solution, which selectively removes the photoresist film and de-crosslinked regions of the spin-on film. The resulting test wafer was characterized for its surface morphology, and it was found that the remaining portions of the spin-on film has a slope that corresponds to the varying exposure dose; the loss of the spin-on film was little to none in the area with the minimal exposure dose (e.g., <1 mJ/cm²), while almost all of the spin-on film was removed in the area with the maximum exposure dose (e.g., >4 mJ/cm²).

FIG. 5A-5C illustrate process flow charts of methods of multipatterning with a crosslinkable overcoat in accordance with various embodiments. Example process flows follow in accordance with the embodiments already described above referring to FIGS. 1A-1F and 2A-2F, and therefore the details will not be repeated.

In FIG. 5A, an example process flow 50 for spacer patterning starts with patterning a photoresist deposited over a substrate using a photolithographic technique (block 510, FIG. 1A), followed by spin coating an overcoat material over the patterned photoresist (block 320, FIG. 1B). Subsequently, the substrate may be exposed to an ultraviolet (UV) irradiation to generate acid in the patterned photoresist (block 530, FIGS. 1C and 1D). The generated acid may then diffuse into a portion of the overcoat material, inducing a crosslinking reaction in the portion of the overcoat material (block 540, FIG. 1E). A developing step may then be performed using a developing solution to remove the patterned photoresist and the overcoat material except the crosslinked portion of the overcoat material (block 550, FIG. 1F), where the remaining crosslinked portion form the spacers.

In FIG. 5B, another process flow 52 for antispacer patterning starts with patterning a photoresist deposited over a substrate using a photolithographic technique (block 512, FIG. 2A), followed by spin coating an overcoat material over the patterned photoresist (block 522, FIG. 2B). Subsequently, a crosslinking reaction may be induced in the overcoat material (block 542, FIG. 2C). The substrate may then be exposed to an ultraviolet (UV) irradiation to generate acid in the patterned photoresist (block 532, FIG. 2D), followed by diffusing the acid into a portion of the crosslinked overcoat material, the diffused acid inducing a de-crosslinking reaction in the portion (block 543, FIG. 2E). A developing step may then be performed using a developing solution to selectively remove the de-crosslinked portion of the overcoat material (block 552, FIG. 2F).

In FIG. 5C, yet another process flow 54 starts with forming a first relief pattern comprising a mandrel over a substrate (block 514, FIG. 1A or 2A), followed by spin coating an overcoat material over the mandrel, where the overcoat material comprises a crosslinker (block 524, FIG. 1B or 2B). The substrate may then be exposed to an ultraviolet (UV) irradiation to generate acid in the mandrel (block 534, FIG. 1D or 2D). The acid may diffuse into portions of the overcoat material and induce a crosslinking or de-crosslinking reaction in the portions (block 544, FIG. 1E or 2E). A development process may then been performed to form a second relief pattern defined by the portions, a pitch size of the second relief pattern is less than that of the first relief pattern (block 554, FIG. 1F or 2F).

Example embodiments of the invention are described below. Other embodiments can also be understood from the entirety of the specification as well as the claims filed herein.

Example 1. A method of processing a substrate includes patterning a photoresist deposited over the substrate to form a plurality of mandrels; spin coating an overcoat material over the plurality of mandrels; exposing the substrate to an ultraviolet (UV) irradiation to generate acid in the plurality of mandrels; diffusing the acid into a portion of the overcoat material, the diffused acid inducing a crosslinking reaction in the portion to form a crosslinked portion of the overcoat material; and performing a developing process using a developing solution to remove the plurality of mandrels and the overcoat material except the crosslinked portion of the overcoat material.

Example 2. The method of example 1, further includes performing a post-exposure bake process after exposing to the UV irradiation.

Example 3. The method of one of examples 1 or 2, further includes baking, after the spin coating, to remove a solvent used for the spin coating.

Example 4. The method of one of examples 1 to 3, where the exposing to the UV irradiation is performed using a photomask.

Example 5. The method of one of examples 1 to 4, where the developing solution includes an aqueous solution of tetramethyl ammonium hydroxide (TMAH).

Example 6. The method of one of examples 1 to 5, where the photoresist includes a photo-acid generator (PAG) that generates the acid in response to the UV irradiation.

Example 7. The method of one of examples 1 to 6, where the acid diffusion is performed by a thermal treatment.

Example 8. The method of one of examples 1 to 7, where the spin coating is performed prior to the exposing to the UV irradiation.

Example 9. The method of one of examples 1 to 8, where the spin coating is performed after the exposing to the UV irradiation.

Example 10. A method of processing a substrate includes patterning a photoresist deposited over the substrate to form a plurality of mandrels; spin coating an overcoat material over the plurality of mandrels; inducing a crosslinking reaction in the overcoat material; exposing the substrate to an ultraviolet (UV) irradiation to generate acid in the plurality of mandrels; diffusing the acid into a portion of the crosslinked overcoat material, the diffused acid inducing a de-crosslinking reaction in the portion; and performing a developing process using a developing solution to selectively remove the de-crosslinked portion of the overcoat material.

Example 11. The method of example 10, where the developing solution includes n-butyl acetate (NBA).

Example 12. The method of one of examples 10 or 11, where the overcoat material includes a vinyl ether crosslinker.

Example 13. The method of one of examples 10 to 12, where the crosslinked overcoat material includes an acetal linkage.

Example 14. The method of one of examples 10 to 13, where the crosslinking reaction is induced by a thermal process.

Example 15. The method of one of examples 10 to 14, where the acid diffusion is performed by a thermal treatment.

Example 16. A method of double patterning includes forming a first relief pattern including a mandrel over a substrate; spin coating an overcoat material over the mandrel, the overcoat material including a crosslinker; exposing the substrate to an ultraviolet (UV) irradiation to generate acid in the mandrel; diffusing the acid into portions of the overcoat material, the diffused acid inducing a crosslinking or de-crosslinking reaction in the portions; and performing a development process to form a second relief pattern defined by the portions, a pitch size of the second relief pattern is less than that of the first relief pattern.

Example 17. The method of example 16, where the diffused acid induces the crosslinking reaction, and where the development process removes the mandrel and remaining portions of the overcoat material that were not crosslinked.

Example 18. The method of one of examples 16 or 17, further includes prior to the acid diffusion, crosslinking all of the overcoat material, where the diffused acid incudes the de-crosslinking reaction, and where the development process removes the portions.

Example 19. The method of one of examples 16 to 18, where the first relief pattern is formed using a photolithographic technique, and where the second relief pattern has a critical dimension below an optical resolution of the photolithographic technique.

Example 20. The method of one of examples 16 to 19, where one of the portions has a width between 1 nm and 15 nm.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a substrate, the method comprising:
patterning a photoresist deposited over the substrate to form a plurality of mandrels;
spin coating an overcoat material over the plurality of mandrels;
exposing the substrate to an ultraviolet (UV) irradiation to generate acid in the plurality of mandrels;
diffusing the acid into a portion of the overcoat material, the diffused acid inducing a crosslinking reaction in the portion to form a crosslinked portion of the overcoat material; and
performing a developing process using a developing solution to remove the plurality of mandrels and the overcoat material except the crosslinked portion of the overcoat material.

2. The method of claim 1, further comprising, performing a post-exposure bake process after exposing to the UV irradiation.

3. The method of claim 1, further comprising baking, after the spin coating, to remove a solvent used for the spin coating.

4. The method of claim 1, wherein the exposing to the UV irradiation is performed using a photomask.

5. The method of claim 1, wherein the developing solution comprises an aqueous solution of tetramethyl ammonium hydroxide (TMAH).

6. The method of claim 1, wherein the photoresist comprises a photo-acid generator (PAG) that generates the acid in response to the UV irradiation.

7. The method of claim 1, wherein the acid diffusion is performed by a thermal treatment.

8. The method of claim 1, wherein the spin coating is performed prior to the exposing to the UV irradiation.

9. The method of claim 1, wherein the spin coating is performed after the exposing to the UV irradiation.

10. A method of processing a substrate, the method comprising:
patterning a photoresist deposited over the substrate to form a plurality of mandrels;
spin coating an overcoat material over the plurality of mandrels;
inducing a crosslinking reaction in the overcoat material;
exposing the substrate to an ultraviolet (UV) irradiation to generate acid in the plurality of mandrels;
diffusing the acid into a portion of the crosslinked overcoat material, the diffused acid inducing a de-crosslinking reaction in the portion; and
performing a developing process using a developing solution to selectively remove the de-crosslinked portion of the overcoat material.

11. The method of claim 10, wherein the developing solution comprises n-butyl acetate (NBA).

12. The method of claim 10, wherein the overcoat material comprises a vinyl ether crosslinker.

13. The method of claim 10, wherein the crosslinked overcoat material comprises an acetal linkage.

14. The method of claim 10, wherein the crosslinking reaction is induced by a thermal process.

15. The method of claim 10, wherein the acid diffusion is performed by a thermal treatment.

16. A method of double patterning, the method comprising:
forming a first relief pattern comprising a mandrel over a substrate;
spin coating an overcoat material over the mandrel, the overcoat material comprising a crosslinker;
exposing the substrate to an ultraviolet (UV) irradiation to generate acid in the mandrel;
diffusing the acid into portions of the overcoat material, the diffused acid inducing a crosslinking or de-crosslinking reaction in the portions; and
performing a development process to form a second relief pattern defined by the portions, a pitch size of the second relief pattern is less than that of the first relief pattern.

17. The method of claim 16, wherein the diffused acid induces the crosslinking reaction, and wherein the development process removes the mandrel and remaining portions of the overcoat material that were not crosslinked.

18. The method of claim 16, further comprising, prior to the acid diffusion, crosslinking all of the overcoat material, wherein the diffused acid incudes the de-crosslinking reaction, and wherein the development process removes the portions.

19. The method of claim 16, wherein the first relief pattern is formed using a photolithographic technique, and wherein the second relief pattern has a critical dimension below an optical resolution of the photolithographic technique.

20. The method of claim 16, wherein one of the portions has a width between 1 nm and 15 nm.
